(19) United States
(12) Patent Application Publication
(10) Pub. No.: US 2025/0021729 A1
(43) Pub. Date: Jan. 16, 2025

(54) POROSITY-ASSISTED FACIES MODELING FOR HYDROCARBON EXTRACTION

(71) Applicant: Saudi Arabian Oil Company, Dhahran (SA)

(72) Inventors: Xingquan Zhang, Dhahran (SA); Abdullah S. Alqasem, Dhahran (SA)

(21) Appl. No.: 18/349,661

(22) Filed: Jul. 10, 2023

(51) Int. Cl. G06F 30/28

(52) U.S. Cl. CPC G06F 30/28

(57) ABSTRACT

Methods and systems for extracting hydrocarbons from a subsurface region include receiving, from a wells of a reservoir, well logs; determining, from facies data of the well logs, facies proportions associated with the subset of wells; determining, from porosity data of the well logs, facies probability functions for the wells; determining, based on the facies probability functions, facies proportions at the wells; updating the facies proportions at the wells using the facies proportions of the subset of wells; based on the updated facies proportions at the wells, generating a three-dimensional (3D) facies trend model for the subsurface region at each of the wells of the plurality; and generating, based on the 3D facies trend model, extended facies data for one or more wells of the wells that are not in the subset of wells that are associated with facies data.

### TECHNICAL FIELD

The present disclosure generally relates to determining subsurface properties of a reservoir in a geological region to facilitate extraction of hydrocarbons. Specifically, the present disclosure relates to predicting facies in the reservoir by recovering missing facies data associated with porosity wells in the reservoir.

### BACKGROUND

A reservoir in a geological region can include one or more wells that are drilled into the subsurface of the reservoir. The one or more wells can be configured to gather well log data at locations in which the one or more wells are drilled. The well log data may represent facies of the rock at or near the one or more wells that are drilled. Rock facies encompasses all the characteristics of a rock including its chemical, physical, and biological features that distinguish it from adjacent rock.

### SUMMARY

This disclosure describes methods and systems for porosity-assisted facies modeling. To perform the porosity-assisted facies modeling, a data processing system is configured to process porosity data from one or more wells. The data processing system generates, based on the processed porosity data, facies probability functions for each of the facies types. The facies probability functions each represent a likelihood that a respective facies is present at a well corresponding to the porosity data for that well. The data processing system generates three-dimensional (3D) facies probability trend models for each facies based on the facies probability logs. The 3D facies probability trend models are further guided by two-dimensional (2D) facies trend maps. The data processing system builds a facies model for the reservoir using the facies probability trend models. The data processing system extracts, from the facies model, facies data that are structured into extended facies data that include predicted facies data for different portions of the reservoir subsurface. The data processing system retrieves existing facies data from the well logs. The data processing system combines the existing facies data with the extended facies data to generate extended facies logs. The extended facies logs represent a fuller data set than that which can be obtained from the existing facies data alone. The data processing system generates a final facies model based on the extended facies data. The final facies model, which incorporates facies predicted from the porosity data of the well logs, includes a greater precision of modeled facies within the subsurface of the reservoir relative to the original facies model generated from existing facies data from the well logs. The final facies model can enable improvements for determining where in a reservoir to explore for hydrocarbon deposits. For example, the final facies model can be an input for additional modeling that controls where to perform drilling in the reservoir. In some implementations the facies model may be used to control drilling in the reservoir

The described implementations can provide various benefits. In the oil and gas industry, a reservoir generally includes fewer wells logs that have high quality facies data in comparison to having high quality porosity data in the well logs. Here, high-quality data refers to data within a threshold accuracy of the true representation of the subsurface near the well. For wells having good porosity data but not good facies data, the facies near the well can be conventionally estimated in a random manner.

The number of wells having facies data is less than the number of wells having porosity data because facies data is generated based on measurements of other types of data in the well logs, and the generation of facies data is not always possible for well in the reservoir. For example, the facies data (facies log) are often predicted with a combination of well logs through neural network algorithms. The cored wells with detailed facies description are used to train the neural network to identify the known log patterns. A computing system (such as the data processing system) applies that learning to other wells with the same number of logs. However, the computing system can fail to predict facies if one or more logs are missing. The number of wells with predicted facies is therefore limited to wells without missing logs. Therefore, there are commonly less wells with predicted facies than wells with porosity logs.

Generally, the randomly estimated facies values are not consistent with porosity responses. For example, a high porosity well can be associated with shaly facies. In another example, a low porosity well can be associated with sandy facies. The predicted facies cannot cover the full porosity ranges, typically the high porosity values, and as a result, the porosity histograms for similar well logs are different depending on whether facies data are included. The result is that there are inconsistencies in the well log data. A data processing system may not be able to perform porosity histogram reproduction when porosity is modeled by facies.

To overcome these issues, this disclosure describes a process to perform porosity-assisted facies modeling in which missing facies data are reconstructed from porosity values of the well logs. In the reservoir, the facies control porosity distribution, and so porosity data are predictive of facies types. The data processing system generates a facies model in which all porosity values have corresponding facies control. The data processing system fully utilizes log data from porosity wells which initially lacked facies. In other words, the data processing system overcomes a technical problem in which, because facies data are difficult to obtain using conventional sensors and hardware that are included in well bore holes for gathering well logs, porosity data are used as a proxy to estimate values for facies data near the wells.

The data processing system enables high quality faces models without the corresponding expense of introducing additional sensor hardware into the reservoir. Generally, there are a smaller number of facies-optimized wells than porosity-optimized wells, as previously discussed. This is in part because facies prediction requires more logs, and therefore more sensors, for accuracy. Porosity data are an input for facies prediction because facies type controls to porosity distribution; else, the facies model is useless. Conventionally, at well locations with porosity input only, facies are stochastically populated. Even with the control of nearby wells, the resulting facies do not have good relationship with porosity. High porosity may have poor facies, or low porosity may have good facies, and so on. This approach can be prohibitive to further numerical reservoir simulation because water saturation is highly related to facies.

The data processing system uses the porosity data to predict facies based on facies probabilities functions. For a specific porosity value, the corresponding facies is one of a subset of facies. The data processing system predicts a probability for the presence of a specific facies based on the generated facies probabilities functions. Instead of specifying a distinct facies code, the data processing system predicts facies at wells with porosity data only. The result is variable. The data processing system can subsequently extract facies logs from the facies model. For wells with facies, the extracted facies are the same as the facies input because facies data is directly measured. For wells with porosity data, the data processing system predicts the extracted facies based on the facies probabilities functions, which can be controlled by nearby wells. The extracted facies data are called extended facies. The data processing system combines the extended facies data with existing facies data to generate extended facies logs for the reservoir. The data processing system uses the extended facies data for generating the final facies model. The result of the generation of the final phase facies mode is that all porosity values have corresponding facies control such that there is facies data covering a full porosity range. This data coverage greatly simplifies porosity histogram reproduction for later generation of models of the reservoir.

The processes performed by the data processing system improve over existing methodologies in several ways. The data processing system ensures that there are facies data covering the entire reservoir and range of porosity values. When facies data are randomly populated, the resulting model may not be in line with porosity response, and the target facies percentages are fixed. the data processing system described herein enables a facies model that is in line with porosity response and in which target facies percentages are flexible, not fixed.

The data processing system described herein is configured to improve over processes in which facies are manually defined. the data processing system can define facies in addition to those that can be defined based on a gamma-ray (GR) log or something similar for facies with clear response, such as clean sand with low GR or mudstone with high GR. Facies with high and low permeability are defined using a GR log. These facies can work as flow thief zones or buffer zones. the data processing system described herein is configured to further identify other facies that cannot be simply identified by GR log only.

the data processing system described herein is configured to provide a model in which target facies percentages are not fixed, but flexible. For example, a data processing system that uses a 3D GR model (or some log with good relationship with facies) as a pseudo-seismic attribute for co-simulation can predict facies, but in a static way. The GR well should be more than facies wells, so wells without facies can be controlled based on facies probability functions. The result is stochastic, so uncertainty can be quantified, but the drawback is that target facies percentages are fixed because facies wells are not updated. the data processing system described herein enables prediction of facies that can be updated as new porosity data are retrieved.

The technical advantage in the proposed solution is to estimate facies for wells with porosity and lacks facies using porosity log data. The data processing system builds the final 3D facies model with the updated facies wells. The facies model agrees with porosity response and target facies percentages are updated. The uncertainty of facies percentages is also quantified. The flexibility of the generated facies data enable integration with commercial packages, such as Petrel, RMS, and SKUA/GOCAD. The data processing system can be integrated with devices configured to control drilling of wells in the reservoir.

In an aspect, a process for porosity-assisted facies modeling for extracting hydrocarbons from a subsurface region includes receiving, from a plurality of wells of a reservoir, well log data measured by sensors in each of the wells of the plurality of wells, the well log data representing porosity measurements of the subsurface region at each of the wells of the plurality, wherein at least a subset of the wells are associated with facies data representing facies at the subset of the wells; determining, from the facies data, facies proportions associated with the subset of wells; determining, from the porosity data, facies probability functions for the plurality of wells; determining, based on the facies probability functions, facies proportions at the plurality of wells; updating the facies proportions at the plurality of wells using the facies proportions of the subset of wells; based on the updated facies proportions at the plurality of wells, generating a three-dimensional (3D) facies trend model for the subsurface region at each of the wells of the plurality; and generating, based on the 3D facies trend model, extended facies data for one or more wells of the plurality of wells that are not in the subset of wells that are associated with facies data.

In some implementations the process includes determining, based on the extended facies data, reservoir volumetrics data for the subsurface region; and determining, based on the reservoir volumetrics data, a location in the subsurface region that includes hydrocarbon deposits.

In some implementations the process includes drilling, at the location in the subsurface region, a well.

In some implementations the process includes receiving geological maps data; generating an areal trend map; and generating, based on the areal trend map, the 3D facies trend model.

In some implementations the process includes detecting, in the facies data of the well log data, vertical trends in facies in the subsurface region; generating vertical proportion curves from the vertical trends in the facies data; and generating, based on the vertical proportion curves, the 3D facies trend model.

In some implementations the extended facies data represent facies that are present at each of the plurality of wells.

In some implementations, the subset of wells include cored wells from which facies data are directly measured.

In a general aspect, a system for extracting hydrocarbons from a subsurface region includes at least one processor; and a memory storing instructions that, when executed by the at least one processor, cause the at least one processor to perform operations including the processes described herein.

In a general aspect, one or more non-transitory computer-readable media storing instructions to cause at least one processor to perform operations the processes described herein.

The details of one or more embodiments are set forth in the accompanying drawings and the description below. Other features and advantages will be apparent from the description and drawings, and from the claims.

### BRIEF DESCRIPTION OF THE DRAWINGS

FIG. 1 illustrates a flow diagram for reservoir properties modeling.

FIGS. 2A-2B each illustrates a porosity histogram.

FIG. 3 illustrates a flow diagram for generating an extended facies prediction for wells with porosity input.

FIG. 4 illustrates a visualization of facies probability functions derived from the upscaled porosity log.

FIGS. 5A-5C illustrate a facies proportions lumping process.

FIGS. 6A-6C illustrate facies trend maps.

FIG. 7 illustrates a visualization of a conceptual facies model.

FIGS. 8A-8C illustrate a facies trend model.

FIG. 9 illustrates a top view of a facies model.

FIG. 10 is a graph that illustrates a comparison of the original facies (FA) data with the extended facies (CFA) data.

FIGS. 11A-B include graphs that illustrate a comparison of an original porosity distribution (FIG. 11A) and the extended-facies-colored porosity distribution (FIG. 11B).

FIG. 12 illustrates a top view of a final facies model.

FIG. 13 illustrates a porosity model histogram colored by extended facies.

FIG. 14 illustrates a histogram of the porosity model and upscaled cells.

FIG. 15 illustrates a flow diagram for porosity-assistant facies modeling and reservoir properties modeling.

FIG. 16 illustrates a flow diagram for porosity-assisted facies modeling.

FIG. 17 is a diagram of an example computing system.

### DETAILED DESCRIPTION

This specification describes processes and systems for hydrocarbon extraction from a subsurface. Specifically, this specification describes a data processing system configured to perform porosity-assisted facies modeling and a control system for controlling well drilling based on the output of the porosity dash assisted facies modeling.

The data processing system uses porosity well logs as an input for facies prediction at locations in a subsurface. The data processing system uses the porosity data together with other wireline logs, such as GR logs, density logs, and sonic logs, which together are called well logs. The data processing system can use facies data to distinguish porosity high-low trends. For example, clean sand has higher porosity values, while shale has lower porosity values. That is the basis for facies-based modeling techniques.

Generally, the number of core wells is limited, and data from these wells is relatively sparse. The data processing system can predict facies based on wireline logs, but the accuracy of predicted facies is limited because of the limited availability of full wireline logs for reliable facies prediction. However, porosity data are available for almost every well, including horizontal wells, because the porosity data can be processed with a GR log only for clastic formations.

When the data processing system can use facies to distinguish porosity distributions, facies probabilities information can be extracted from porosity logs for generation of facies probability functions. Because of the availability of porosity wells, the data processing system can generate a facies probability model for each facies and use the generated facies probability model for facies prediction.

Rather than randomly drawing facies for wells that have porosity data and not facies data, the data processing system performs facies prediction for those wells using the facies probabilities functions. For example, a high porosity region, indicated in the porosity data, should be sand instead of shale. The data processing system uses porosity data to generate a more reliable facies model and improves its reservoir performance forecast.

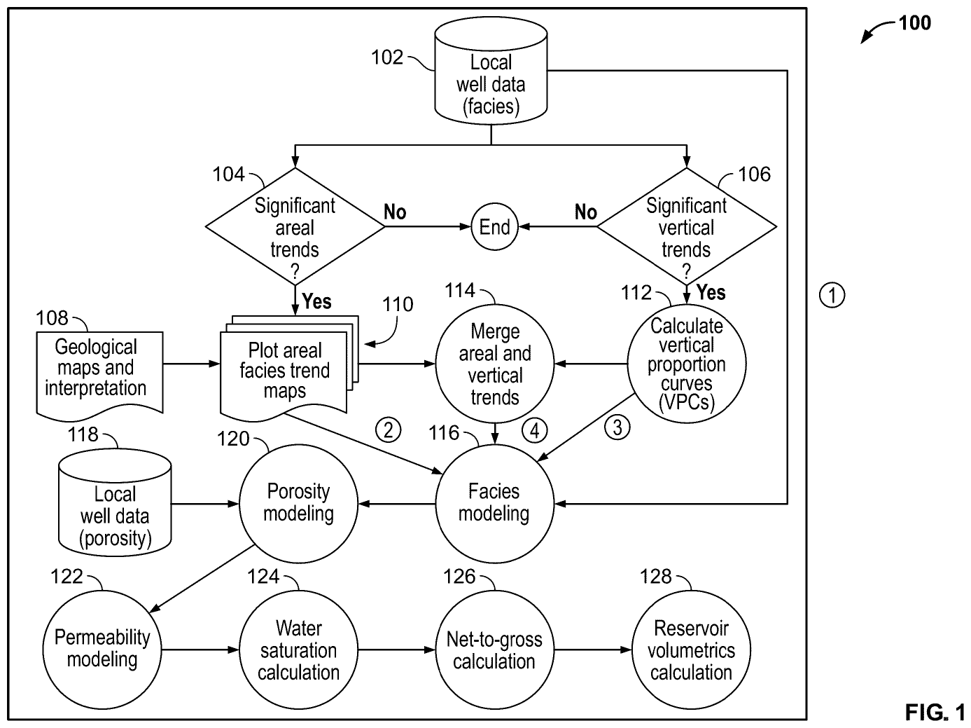

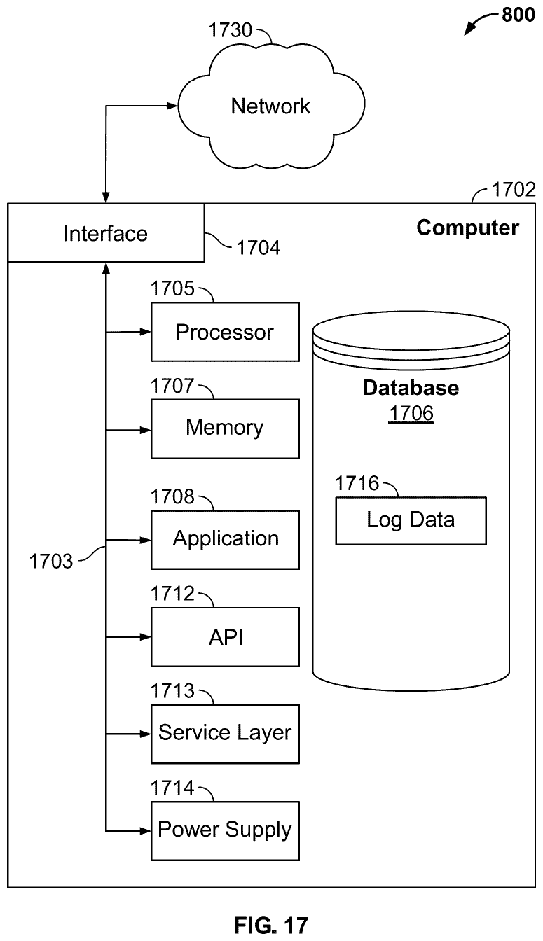

FIG. 1 illustrates a flow diagram of an example process 100 for reservoir properties modeling. The process 100 can be performed by a data processing system, such as a control system associated with reservoir hardware. In some implementations the data processing system includes a computing system as described in reference to FIG. 17.

Petrophysical properties of interest are often highly correlated with facies type. Modeling facies enables a data processing system to condition how the petrophysical properties will be distributed afterwards. For example, knowledge of facies type can constrain a range of variability in porosity and permeability modeled for a subsurface. Moreover, saturation functions depend on the facies even when the distributions of porosity and permeability do not.

For geostatistical modeling purposes, facies are commonly based on different petrological characters. There are distinct reservoir properties between different facies. In other words, facies represent separate regions of a reservoir that have distinct reservoir property input statistics and trends. Facies type has a significant correlation to (and control of) modeled porosity, permeability, or saturation functions. If this correlation does not hold, modeling the three-dimensional distribution of facies provides little benefit because uncertainties in the modeled values is not reduced and the resulting models are not representative or predictive of actual subsurface conditions.

The reservoir properties modeling process 100 of FIG. 1 includes, at step 102, obtaining well log data from wells in the subsurface of the reservoir being modeled. Specifically, facies data are retrieved from a local well database. the facies data our data that are included in well logs that represent the different types of facies detected at each of the well locations represented by the well logs. For example, the local well data can include wireline data obtained from one or more wells in the reservoir. Generally, the facies at each of the one or more wells are determined based on an initial facies modeling workflow. For example, each of the data represented in the wireline log can be characterized to represent one or more different facies. For example, when one or more different types of data in the well logs are within predefined ranges, those data together can be determined to correspond to a particular facies (e.g., using neural networks), as subsequently described.

Generally, the process 100 includes facies modeling, followed by porosity modeling by facies, permeability modeling co-simulated by porosity, water saturation calculation, net-to-gross calculation, and reservoir volumetric calculation, As subsequently described. With this process 100, The data processing system models all reservoir properties (e.g., sequentially). Specifically, in this initial process 100, the data processing system incorporates porosity data into the model after the facies model is ready. Depending on the availability of the areal and vertical trends, there are four choices of facies modeling workflows.

The facies modeling of process 100 is now described in detail. The data processing system executing the process 100 is configured to determine, at step 104, whether there are significant areal trends represented in the log data of the one or more wells. An areal trend refers to a trend, in values of one or more data types of the wireline data logs, that exists over an area of the subsurface. The data processing system executing process 100 is also configured to determine, at step 106, whether there are significant vertical trends in the data of the well logs. a vertical trend refers to a trend, in values of the one or more data types of the wireline data logs, that exists over a vertical region of the subsurface. Depending on the availability of the areal and vertical trends, there are four options of facies modeling.

In process 100, the data processing system is configured to perform facies modeling in situations in which there are no significant aerial trends or significant vertical trends, as now described. In FIG. 1, this is shown as option 1. In this example, the data processing system is configured to generate the facies model, at step 116, with well data input only. The facies percentages derived from wells, and the variograms derived from facies data are used as the main inputs, so the facies model is data-driven. In this example, a geomodeler and a geologist generally verify variogram orientation and ranges of the facies model and perform a quality control check for the resulting facies model. The validation ensures that simulated facies model follows the geological conceptual model and knowledge, because the data processing system uses the resulting facies models to constrain the succeeding porosity model.

In process 100, the data processing system is configured to perform facies modeling in situations in which there are aerial trends but not significant vertical trends, as now described. In FIG. 1, this is shown as option 2. If there are significant areal trends, the data processing system plots, at step 110, the facies areal trend maps and uses them as input for facies modeling add step 116. Well data are preferentially drilled and typically cannot cover the whole area of interest (AOI). Geological knowledge, the conceptual facies model, and geological maps are received, at step 108, and used as input data to predict or establish the trend maps, ensuring that those maps make geological sense. For a geostatistical simulation, commonly probability maps are integrated only, so the facies trend maps are typically facies probability maps, instead of facies thickness maps.

In process 100, the data processing system is configured to perform facies modeling in situations in which there are no aerial trends but there are significant vertical trends, as now described. In FIG. 1, this is shown as option 3. If there are significant vertical trends, the data processing system generates, at step 112, vertical proportion curves (VPCs) and uses these as input for facies modeling at step 116. When a sequence-stratigraphic framework is applied for geological grid building, vertical trends are usually clear because of how the sequences are defined. The VPCs are usually data-driven by well log data and calculated on a layer-by-layer basis. The generated VPCs may be modified if the well data are either not enough or too sparse to capture the trend of vertical variations.

In process 100, the data processing system is configured to perform facies modeling in situations in which there are both aerial trends and vertical trends, as now described. In FIG. 1, this is shown as option 4. If both lateral and vertical trends exist, the data processing system merges the lateral and vertical trends as a consistent three-dimensional trend model. The data processing system merges the plotted aerial facies trend maps and calculated VPC's into a consistent 3D trend model. The data processing system uses the combined trend model for facies modeling at step 116. There are various trends combination techniques, which will not be discussed in detail here. generally, the process 100 works when all porosity wells represented in the local well data at step 102 have facies input. In this case, porosity at each location is well controlled by facies. however as described herein this is not always the case. Therefore, addition of porosity data to determine the facies at each of the one or more wells is performed as described herein.

To correlate facies with porosity, the data processing system includes porosity indication logs, such as density and neutral logs, in analysis for facies prediction. Facies with high porosity values, such as clean sand, or low porosity values, such as anhydrite, are indicators of reservoir-quality rock and flow barriers, respectively. Other facies, such as shaly sand and sandy shale, may cover similar porosity ranges but have different shape and mean values. However, the flow abilities of these facies are very different, and so shaly sand is often a reservoir facies while sandy shale is not.

Generally, there are far fewer facies wells associated with facies data than porosity wells associated with porosity data. For example, the number of facies wells can be ½ to ⅓ of the number of porosity wells, even when only vertical wells are considered. The number of wells having facies data is less than the number of wells having porosity data because facies data is generated based on measurements of other types of data in the well logs, and the generation of facies data is not always possible for well in the reservoir. For example, the facies data (facies log) are often predicted with a combination of well logs through neural network algorithms. The cored wells with detailed facies description are used to train the neural network to identify the known log patterns. A computing system (such as the data processing system) applies that learning to other wells with the same number of logs. However, the computing system can fail to predict facies if one or more logs are missing. The number of wells with predicted facies is therefore limited to wells without missing logs. Therefore, there are commonly fewer wells with predicted facies than wells with porosity logs.

Once the facies are modeled at step 116, the data processing system proceeds to model the porosity of the reservoir. The data processing system receives, at step 118, porosity data from the well log data. In process 100, the data processing system is configured to perform, at step 122, permeability modeling of the reservoir. in process 100, the data processing system is configured to perform, at step 124, water saturation calculations. The data processing system can then perform, at step 126, a net to gross calculation, and reservoir volumetrics calculations at step 128. Steps 122, 124, 126, and 128 of process 100 are used to predict where in the reservoir hydrocarbons may be present. These models are used to guide drilling operations in the reservoir or other hydrocarbon extraction operations in the reservoir.

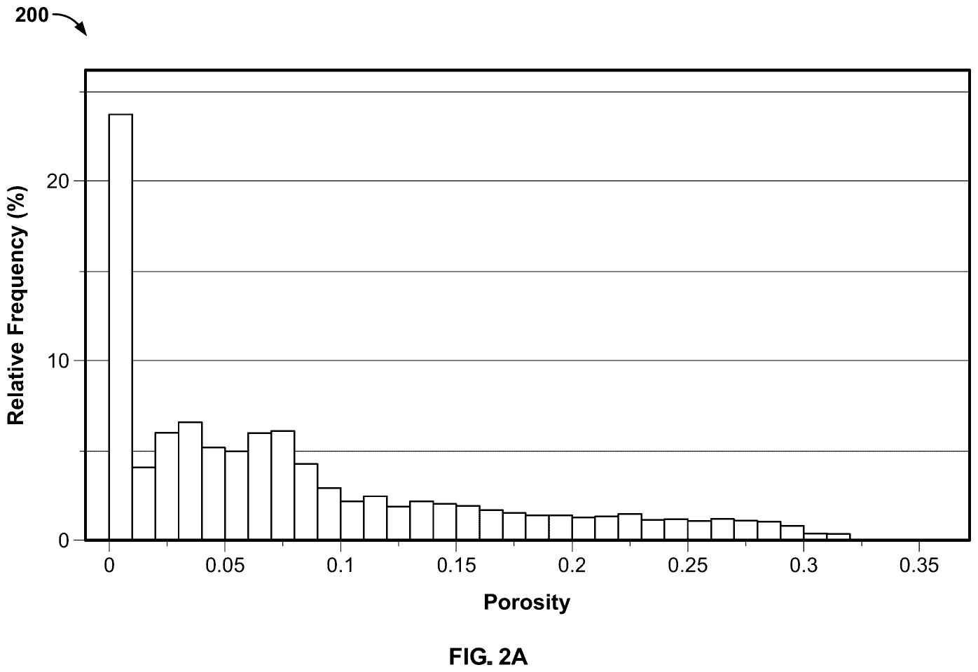

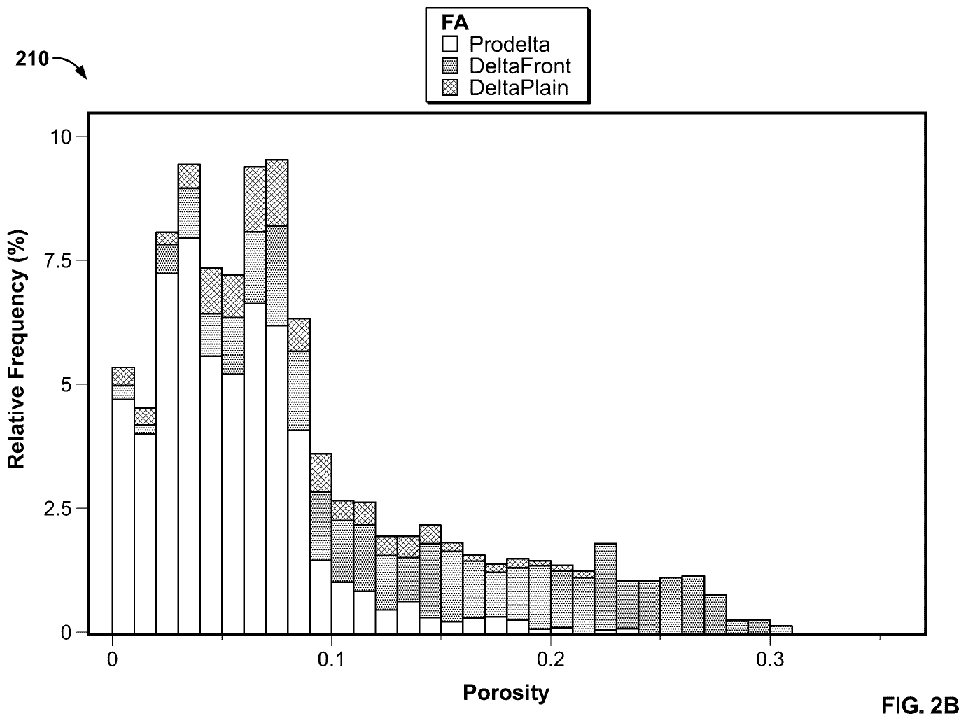

FIGS. 2A-2B each illustrates a porosity histogram. FIG. 2A shows a histogram 200 including porosity data for a reservoir with 217 wells in total. The histogram 200 shows a porosity distribution. There are 116 wells with porosity. There are only 55 wells (e.g., cored wells) associated with facies data, as shown in histogram 210 of FIG. 2B. From the histograms 200, 210, it is shown that the maximum porosity value is not captured in the facies data, and the shapes (with or without facies) are very different. Histogram 200 shows porosity for all wells. Histogram 210 shows porosity for wells with facies and is shaded based on facies associations (FAs), including pro-delta, delta-front, and delta-plain facies.

When there are a smaller number of facies wells than porosity wells, some porosity ranges might not be corresponding to any facies, typically the maximum values. This creates issues as now described. The histogram by facies is different from all porosity values. Both shape and mean are different. The probability density function (PDF) of the model and the PDF of porosity logs are typically compared. The PDF by facies might have gaps if the porosity in some facies has limited number of samples. When this occurs, facies values at wells with porosity log but without facies log can be randomly populated without any constraints. Therefore, a location with high porosity could be predicted as anhydrite, or a low porosity location is predicted as clean sand. Such kind of facies model is misleading because facies controls not only porosity distribution, but also permeability and water saturation distributions. There are difficulties for following numerical reservoir simulations based on these data—the simulations may not be able to execute or have low accuracy.

In some implementations, anhydrite and clean sand distribution are recognized as flow barriers and thief zone facies respectively. In some implementations, anhydrite or clean sand are defined based on porosity or GR logs manually. This is very time consuming if there are large number of wells. Additionally, because many facies cover the same porosity value, assigning deterministic facies values causes consistency issues. The data processing system described herein resolves these issues using a dynamic facies prediction based on porosity input, as previously described.

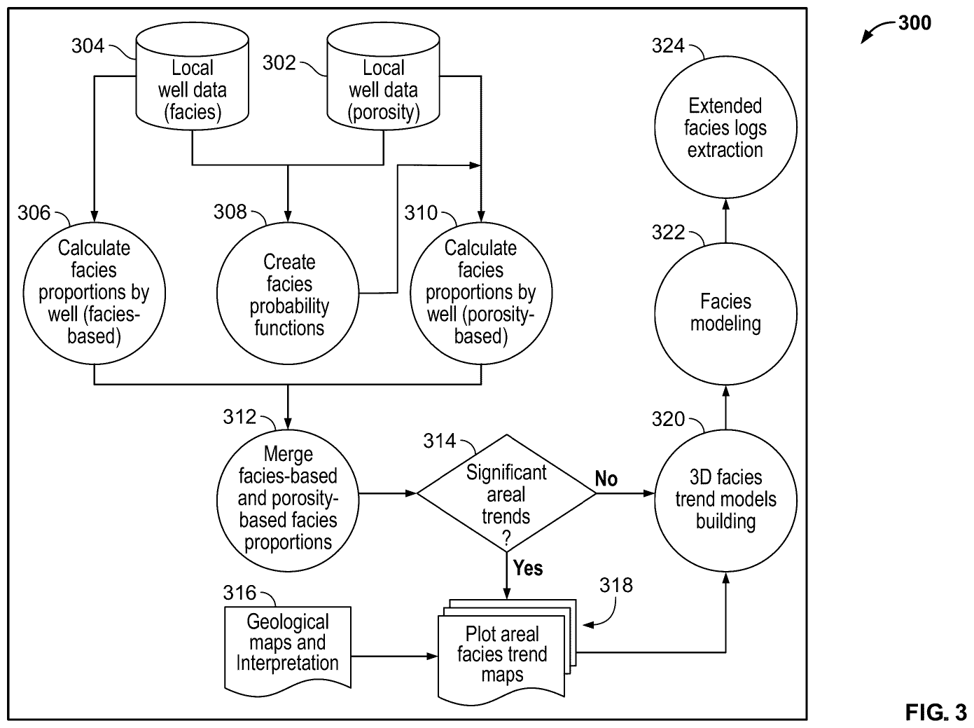

FIG. 3 illustrates a flow diagram 300 for generating an extended facies prediction for wells with porosity input. The data processing system previously described and described in relation to FIG. 17 can be used to execute the process 300. In some implementations the process 300 is similar to process 100 but including some additional steps. The porosity-assisted facies prediction process 300 is described as follows.

For process 300, the data processing system is configured to retrieve data from well logs of the reservoir. As previously described, the well logs include wireline data representing one or more features of the subsurface. The well logs include porosity data 302 that is measured directly from the subsurface using sensors within the wells. The well logs also include facies data 304 which is calculated from one or more other measurements of the well log data as previously described. In some implementations, the facies data are determined based on coring the drilled well.

The data processing system is configured to calculate and combine facies proportions for wells with facies and porosity inputs. Specifically, the process 300 includes determining, by the data processing system at step 306, facies proportions per-well that are facies-based. The data processing system determines the facies proportions based on the facies 304. The facies proportions are calculated for each specific geological interval that is used to define the geological grid, say, a geological sequence, by calculating the cumulative percentage of a facies within this interval at well locations. This is done facies by facies for each geological interval, and the proportions of all facies should sum up to one, or one hundred percent, for each geological interval of a specific well.

The process 300 includes determining, by the data processing system at step 308, facies probability functions, as previously described. The data processing system generates the facies probability functions at step 308 using both the facies data 304 and the porosity data 302. The data processing system uses the generated facies probability functions to determine, at step 310 of the process 300, facies proportions per-well that are based on porosity. The data processing system, in process 300, is configured to merge, at step 312, facies-based and porosity-based facies proportions that were previously generated. These steps are described in further detail below.

The process 300 includes determining, at step 314, if there are significant areal trends of the log data in the subsurface. the data processing system can determine these aerial trends in a similar way as described in relation to process 100 of FIG. 1, previously. if the data processing system determines, at step 314, that significant aerial trends exist, the data processing is configured to plot, at step 318, areal facies trend maps. The areal facies trend maps are based on geological maps and interpretation by the data processing system.

The data processing system is configured to generate, at step 320, 3D facies trend models with facies proportion logs. If areal trends exist, the 3D facies trend models incorporate them. The 3D facies trend models are typically built with ordinary kriging algorithm, and the 2D trend maps generated with step 318 are used as local kriging mean. If areal trends do not exist, simple kriging algorithm is used instead. There are many other algorithms that have the ability to integrate trends data, such as Bayesian kriging and universal kriging.

In process 300, the data processing system is configured to generate, at step 322, a facies model with the facies logs and the 3D facies trend models as main inputs. The data processing system is configured to extract, at step 324, facies logs for wells with facies and porosity inputs. For wells with facies input, the facies log should be the same as the original facies log since they are the conditioning data. For wells with porosity input only, the facies are predicted but they are controlled with the facies trend functions. The extracted facies logs are used for the following facies modeling. From the process 300, the extracted facies logs are not fixed for wells with porosity input only. At those locations, the facies are controlled both by nearby wells with facies, and the facies probability functions.

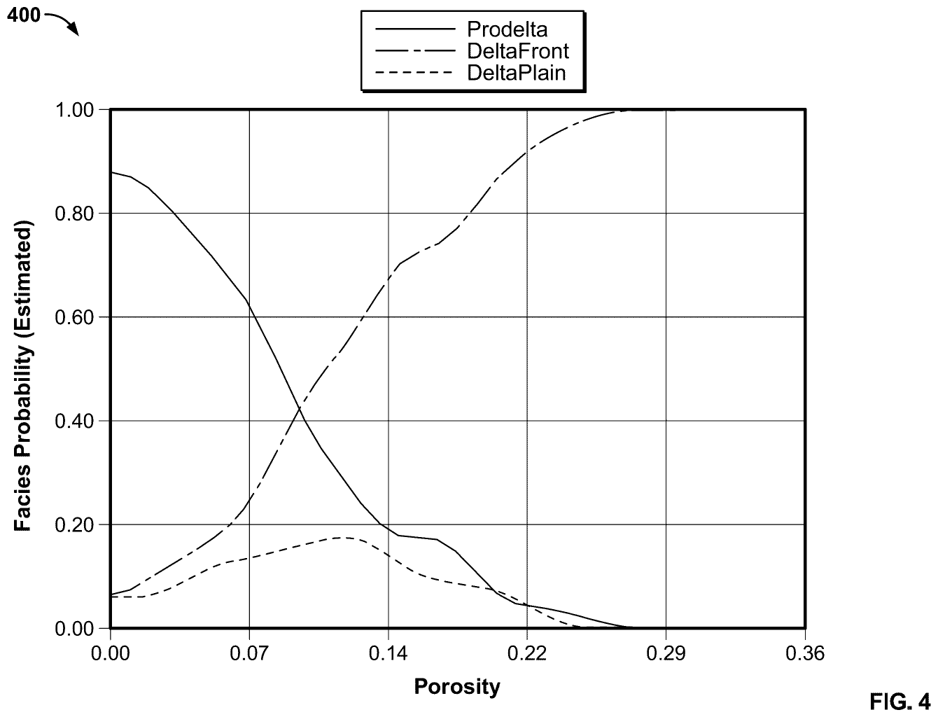

FIG. 4 illustrates a graph 400 of facies probability functions derived from the upscaled porosity log. The data processing system is configured to prepare prerequisite facies probability functions. There are a smaller number of wells with facies than there are wells with porosity, and facies constrain porosity distribution. Therefore, facies probability functions (FPFs) are derived from porosity logs with facies input, which give a probabilistic relation between facies types and porosity values, as shown in graph 400. Smoothing is applied to the data of graph 400 for smoother facies probability functions. Three different probability functions are shown in graph 400. For example, a pro-delta facies probability function is shown, a delta-front facies probability function is shown, and a delta plane facies probability function is shown in graph 400. The data processing system uses the facies probability functions (FPFs) to predict facies probabilities for wells with porosity data but without facies data.

In some implementations, porosity with facies control does not cover the full porosity range. The data processing system extends the probability functions to cover porosity high and low tails. For example, histography 210 of FIG. 2B shows that high porosity values all come from the delta front facies. The data processing system determines that all high porosity values should come from delta front only in this example.

When there are not enough samples in a data range, the resulting facies probability functions might become noisy. In some implementations the facies probability functions are smoothed by the data processing system based on a statistical analysis.

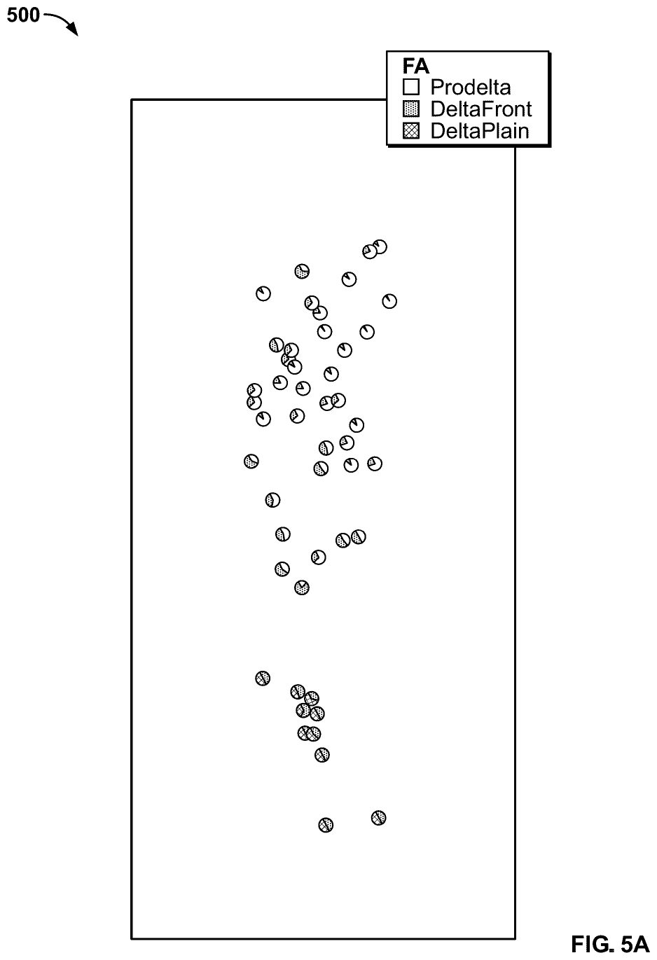

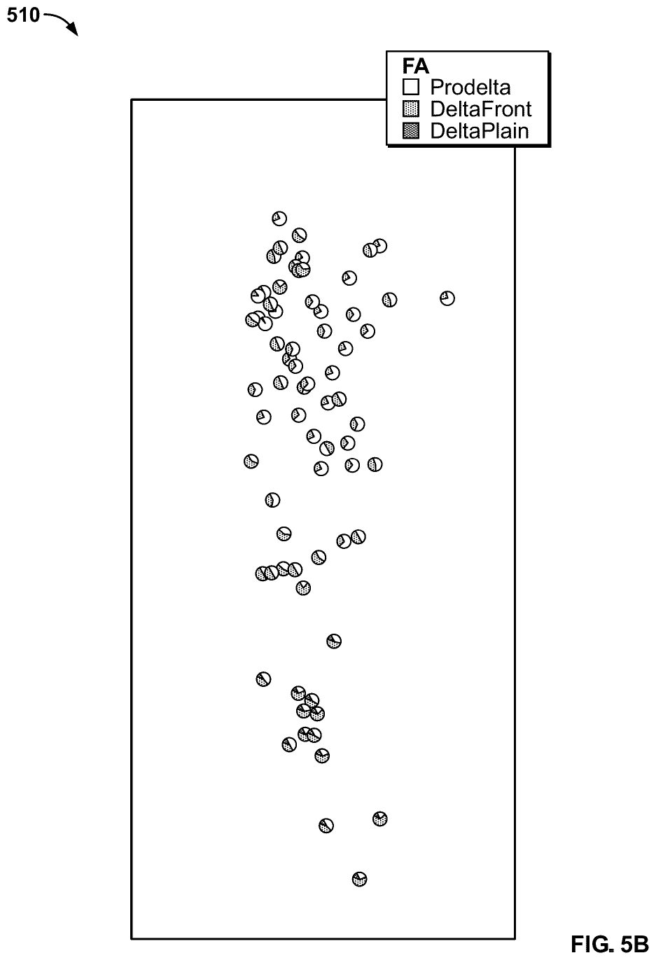

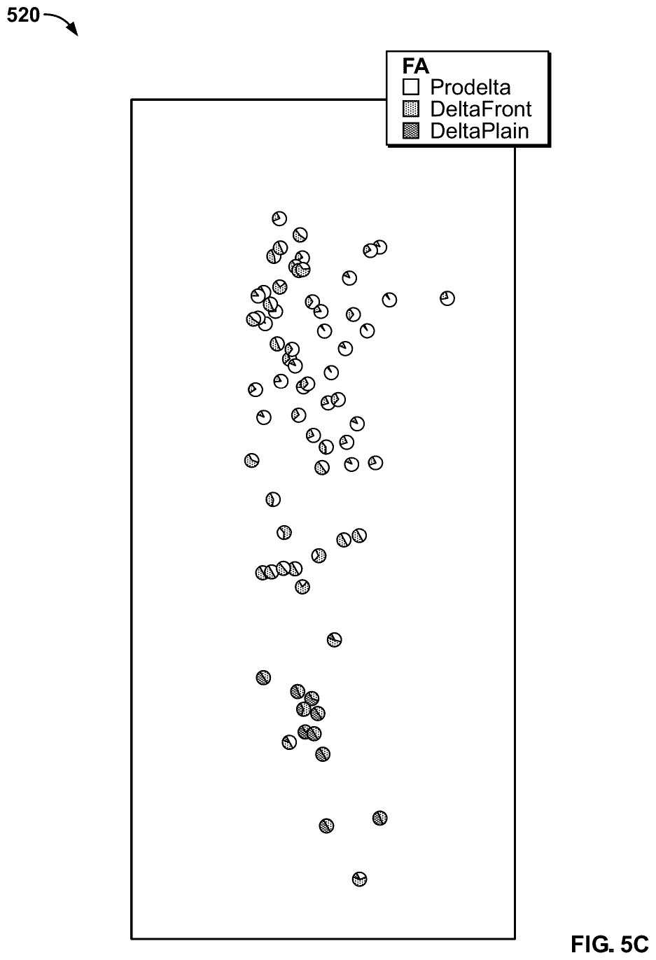

A combined facies proportions calculation process is now described in reference to process 300 of FIG. 3. The data processing system is configured to generate facies probabilities functions in step 308 as previously described. the data processing system is configured to edit the FPFs to cover the full porosity ranges and perform smoothing if necessary. The data processing system is configured to calculate facies proportions for each zone and for all wells in step 310. The data processing system is configured to calculate facies proportions for wells with facies for each grid zone at step 306. The resulting data 500 is shown in FIG. 5A.

FIGS. 5A-5C illustrate a facies proportions lumping process. In FIG. 5A, the data processing system derives the facies proportions 500 from the facies log. In FIG. 5B, the data processing system derives the facies proportions from the facies probability functions. In FIG. 5C, the combined facies proportions 520 are shown.

The data processing system is configured to calculate facies proportions for wells with porosity, in step 310. For each porosity value set, the facies proportions can be easily calculated from the probability functions of FIG. 4. The calculation is done on a zone-by-zone basis as well, as shown by data 510 of FIG. 5B. The porosity-derived facies proportions trend is similar to the facies-log-based trend. There are some differences for wells with both facies and porosity because of the smoothing of the facies probability functions.

In process 300, the data processing system is configured to combine these facies proportions (e.g., of data 500, 510, 520) for each well. For wells with porosity input only, the porosity-derived facies proportions are used. For wells with facies input, the facies-based proportions data 520 are used by the data processing system, as shown in FIG. 5C. This is because the facies log prediction is more reliable since it considers many well logs, and porosity is only one of them.

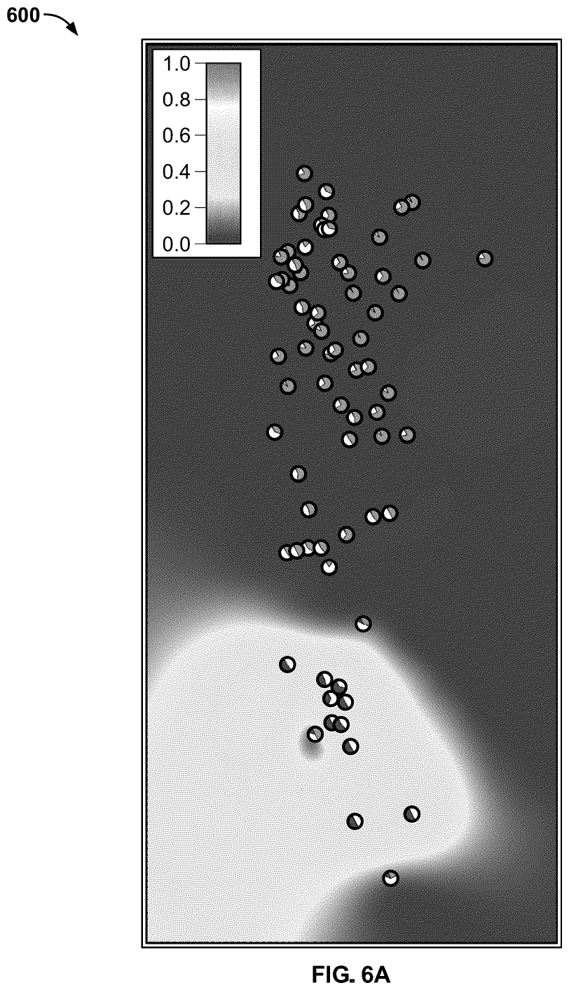

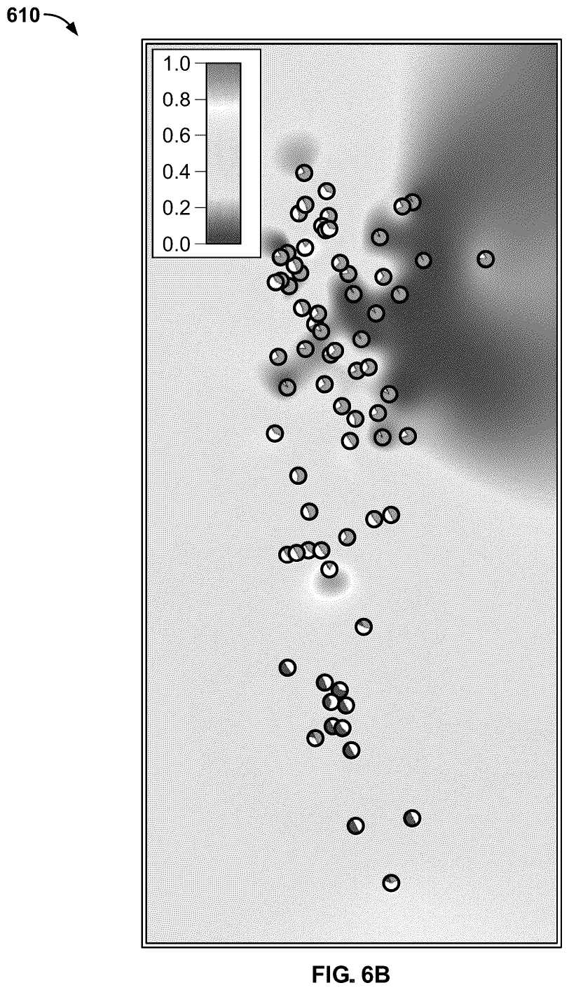

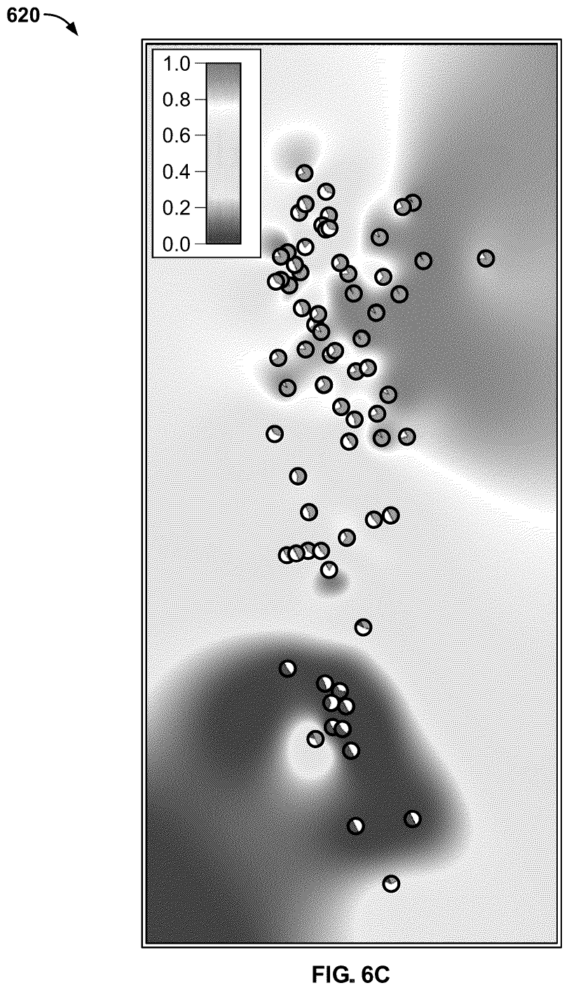

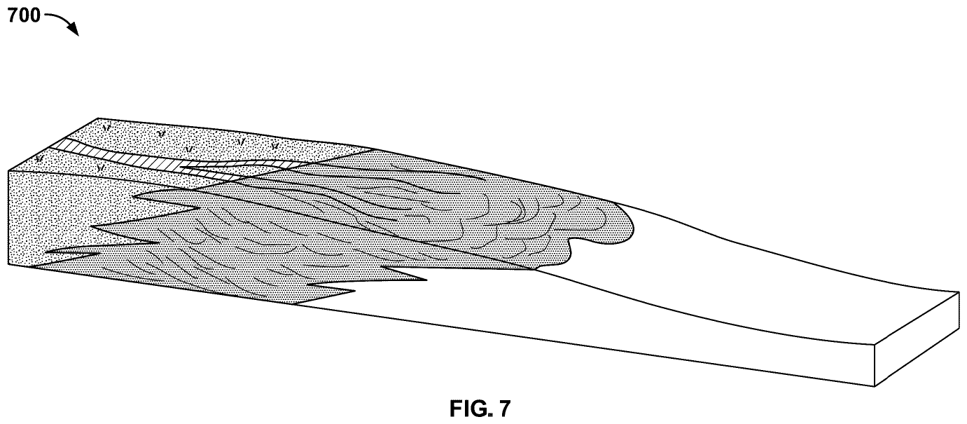

FIGS. 6A-6C illustrate facies trend maps, 600, 610, and 620, respectively. The data processing system performs areal facies trends mapping as described in relation to step 318 of process 300, previously. The data processing system maps the areal facies trends based on a conceptual facies model 700, shown in FIG. 7. For this specific example, the geological environment is a deltaic system. FIG. 6A shows a facies map 600 of a delta plain. FIG. 6B shows a facies map 610 of a delta front. FIG. 6C shows a facies map of a pro-delta.

FIG. 7 illustrates a visualization of a conceptual facies model 700. The delta plain facies association is located mainly in the southwestern area, with main flow direction from southwest to northeast. The pro-delta facies is located mainly in the northeastern area of the map. The delta front facies are in between the delta plain and the pro-delta. The structure of this reservoir is a fold, so all the wells are drilled in the area above water contact, leaving the surrounding areas without any wells. In this case, the geological interpretation is very important to cover the area without well control. Because of sea level changes, and variability of channel distribution, it is common to see some local facies variations. However, the high-low trend of facies proportions is clear.

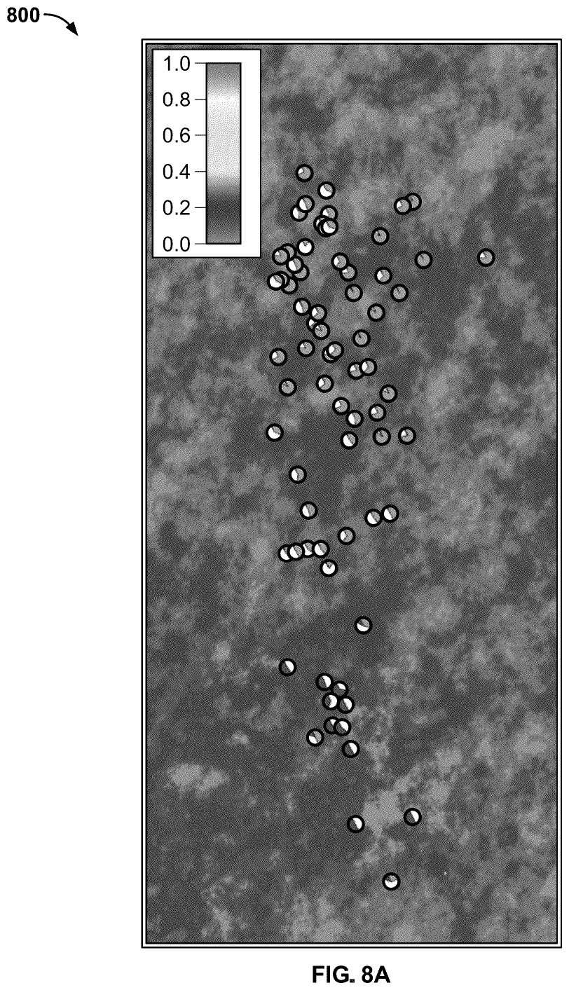

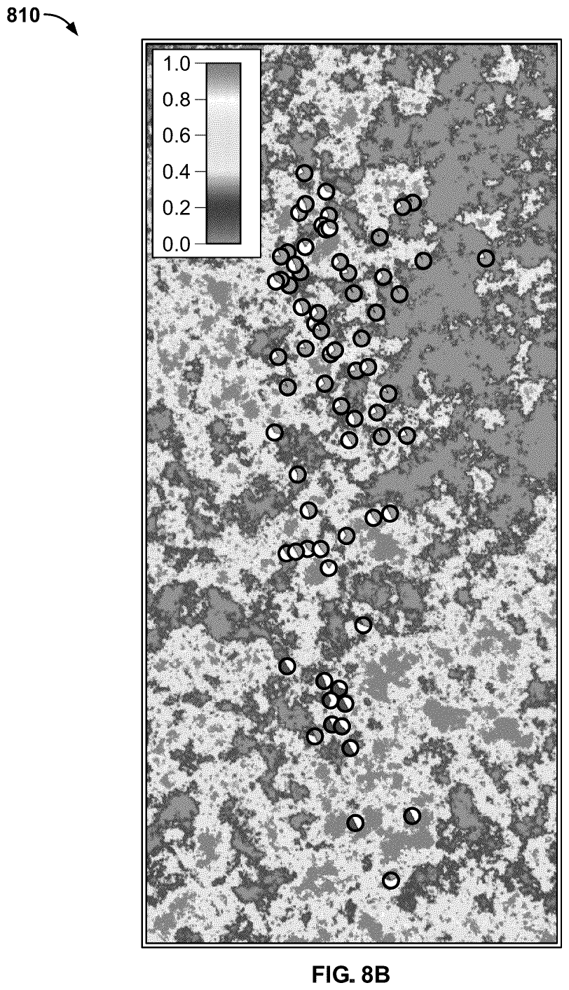

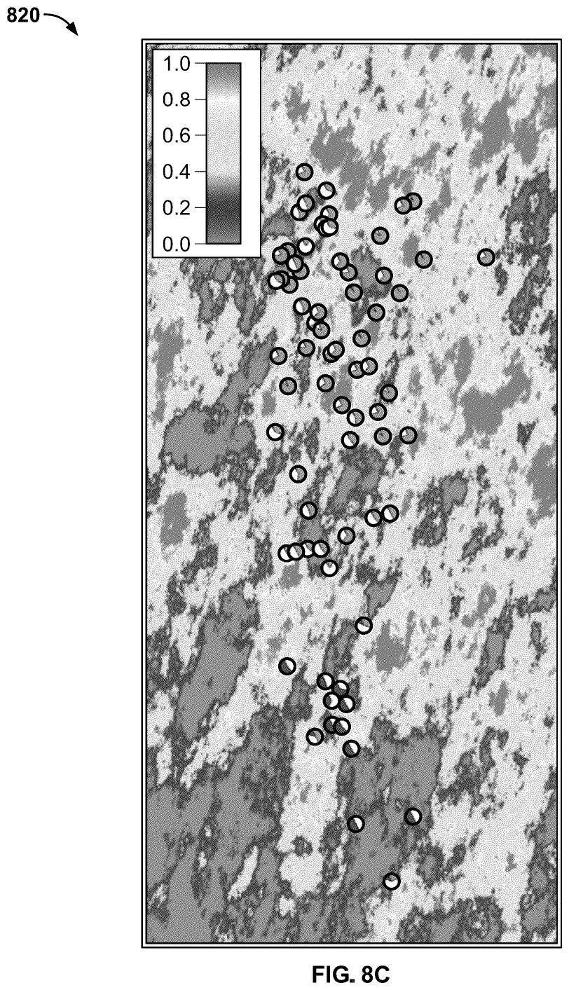

FIGS. 8A-8C illustrate top views of a facies trend model, generated based on step 320 of process 300, described previously. The 3D facies trend models are built with the facies proportion logs, together with the 2D trend maps 600, 610, and 620 from step 318 when facies areal trends exist. FIG. 8A shows a top view of a facies model 800 of the delta plain. FIG. 8B shows a top view of a facies model 810 of a delta front. FIG. 8C shows a facies model 820 of a pro-delta.

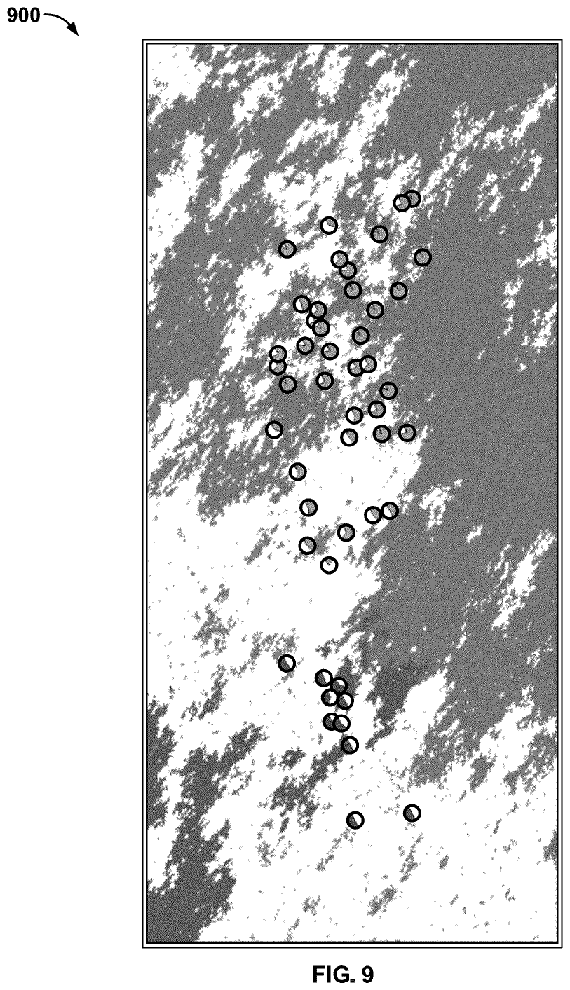

FIG. 9 illustrates a top view of a facies model 900. The data processing system performs facies modeling with the original facies logs. For example, a facies model 900 could be built with the original facies logs together with above facies trend models. The facies model 900 follows the facies trend maps but with some random noise to the east, where there are no wells control. The noise is caused by the trend models. These models are generated at step 322 of process 300, previously described.

The data processing system can generate extended facies logs for all porosity wells and facies wells. The facies model generation of step 322 is to predict facies for wells with porosity only which is controlled by nearby facies wells. Due to the control of the 3D trend model, the predicted facies are in line with porosity response at wells without facies, instead of randomly populated.

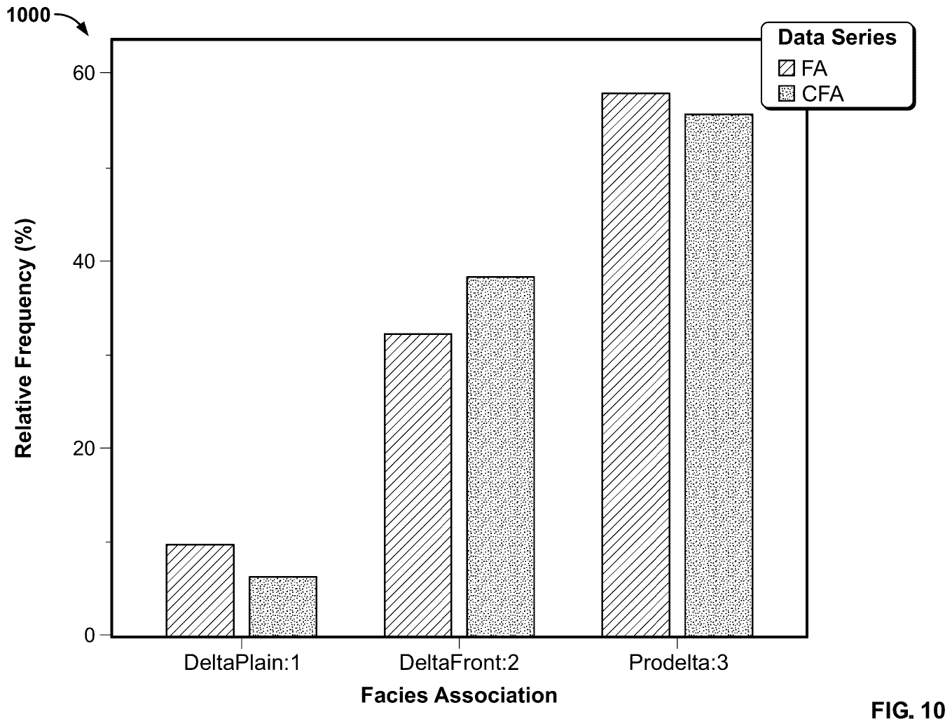

FIG. 10 is a graph 1000 that illustrates a comparison of the original facies (FA) data with the extended facies (CFA) data. The data processing system extracts facies logs from the previous facies model 900 of FIG. 9. For wells with facies, the extracted are the same as the original input. Therefore, the extracted facies are hard data for the facies wells and are predicted soft data for the wells with porosity only. Therefore, the data processing system can extract facies logs as extended facies logs to distinguish them from the original facies logs. When multiple realizations are built, the extended facies logs are variable in line with the facies trend functions. There are some differences between the extended facies and the original facies, as illustrated in the graph 1000.

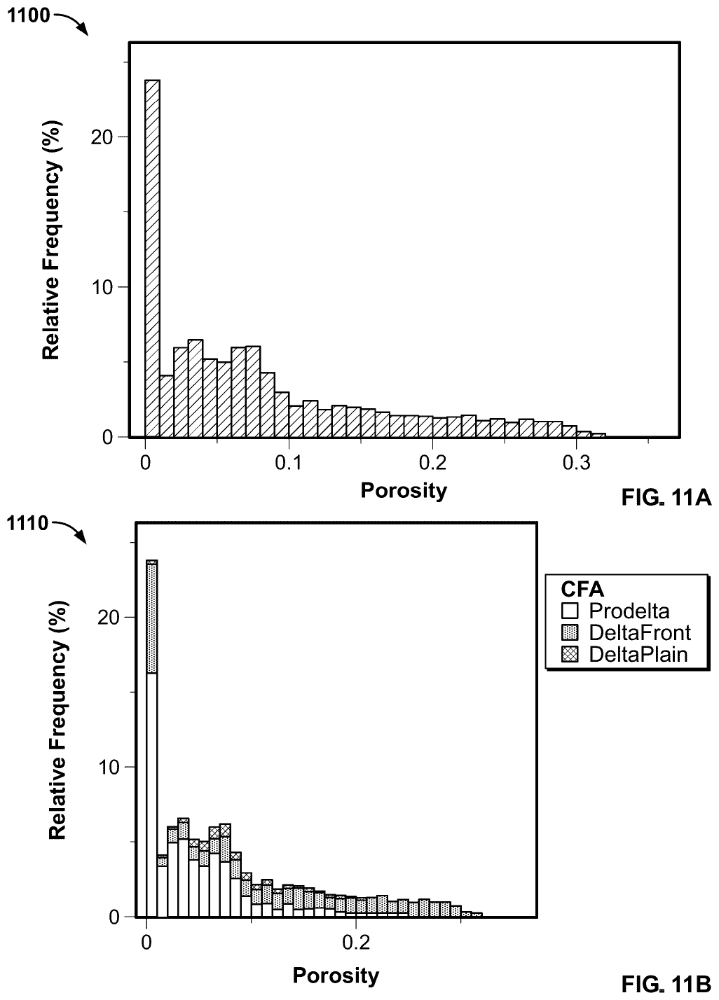

FIGS. 11A-B include histograms 1100, 1110 that illustrate a comparison of an original porosity distribution (FIG. 11A) and the extended-facies-colored porosity distribution (FIG. 11B). The extracted facies will cover all porosity data. The two histograms 1100, 110 have the same number of samples. Recall histograms 200, 210 show the original porosity versus the original facies-colored porosity. The original facies cannot cover the full porosity range. The high values portion does not have facies input. The shapes of two histograms are also different. With those input PDFs, the porosity histogram cannot be reproduced well if porosity is modelled by facies.

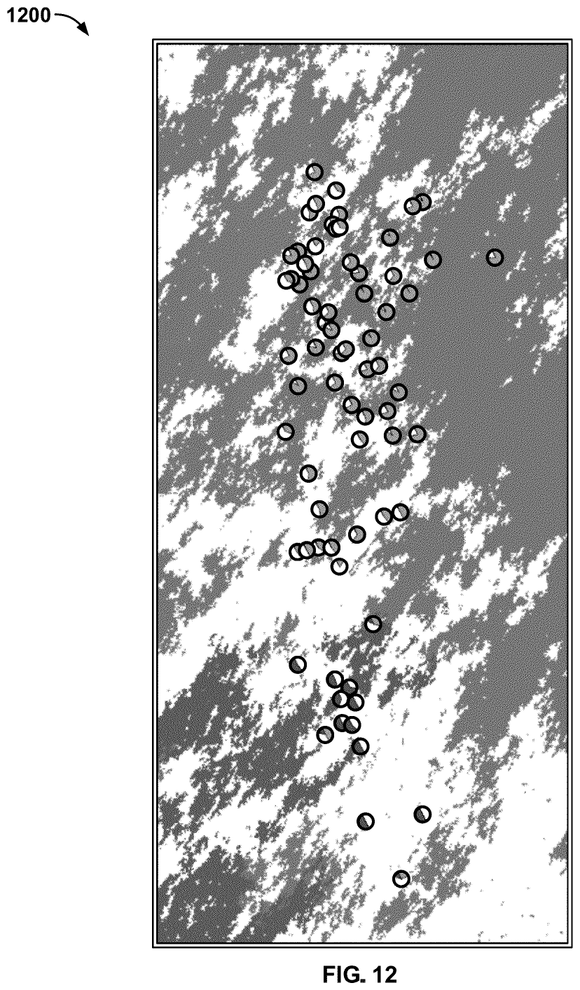

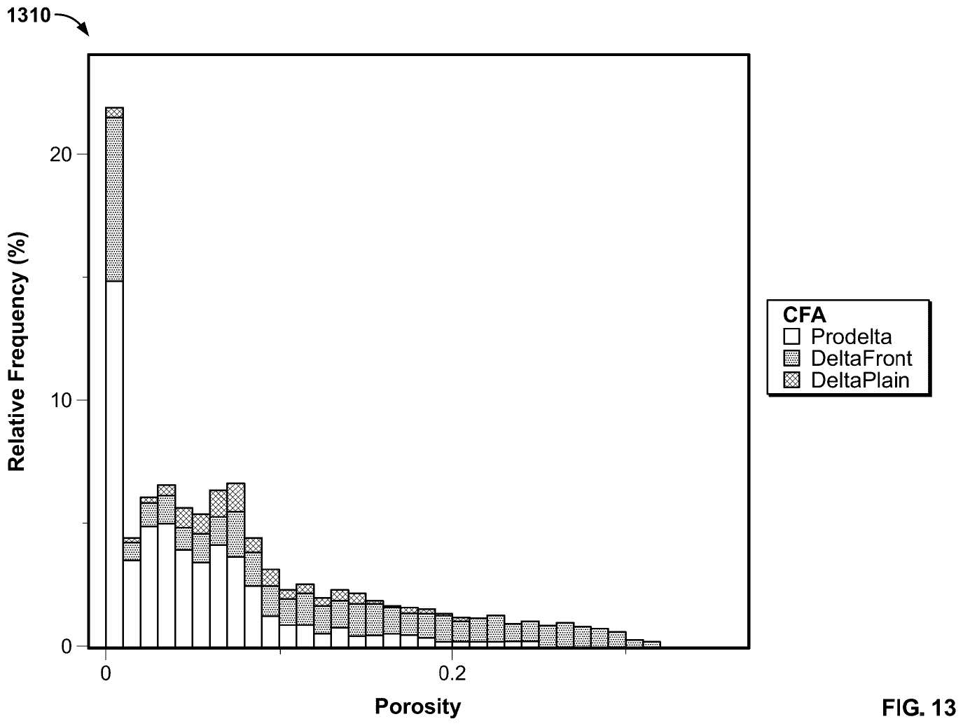

FIG. 12 illustrates a top view of a final facies model 1200. FIG. 13 illustrates a porosity model histogram 1300 colored by extended facies. The data processing system is configured to perform final facies model building with the extracted facies logs. To compare, the final facies model 1200 of FIG. 12 and the associated histogram 1300 of FIG. 13 are built with the same setup as the previous facies model 900. Because more facies wells were used, and because of the impact of porosity, the resulting facies model 1200 is always smoother than the previous version. In addition, because of the porosity control, the facies are consistent with the porosity response. For example, high porosity section (>0.25 in this case) is a delta front facies only.

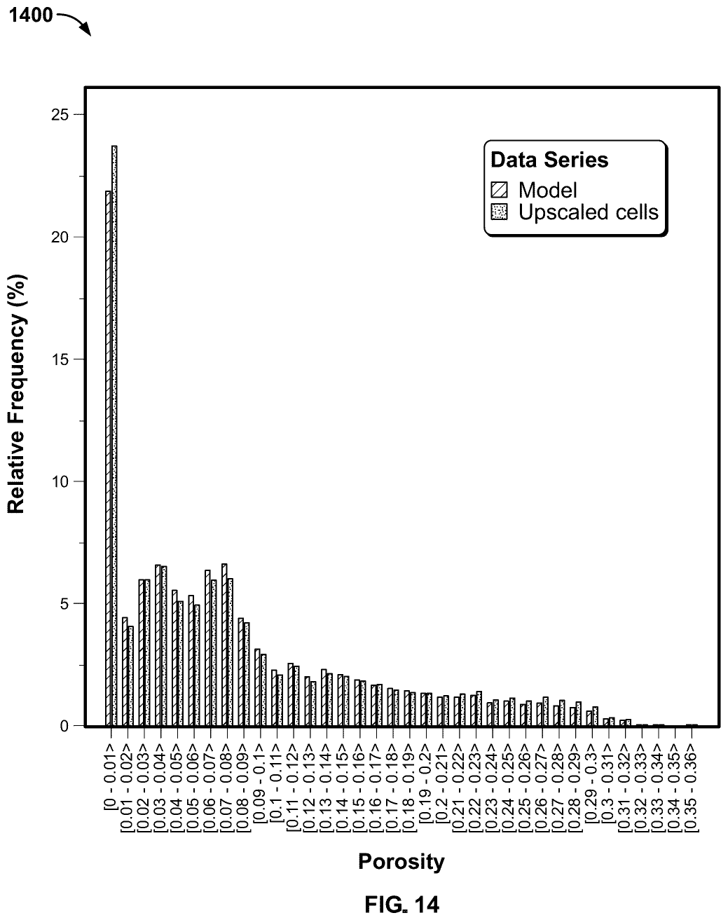

The porosity model histograms reproduction is now described. The data processing system generates the porosity model using the extended facies model with a sequential gaussian simulation (SGSIM) algorithm. Because all porosity values have corresponding facies input, the porosity model histogram reproduces the input porosity by facies closely, as shown in FIG. 14. FIG. 14 illustrates a histogram 1400 of the porosity model and upscaled cells. The high porosity values are all within the delta front facies. Comparing the porosity model and the upscaled cells, the input well data mean, and histogram shape (PDF) are all reproduced within a threshold accuracy (e.g., within a few percent).

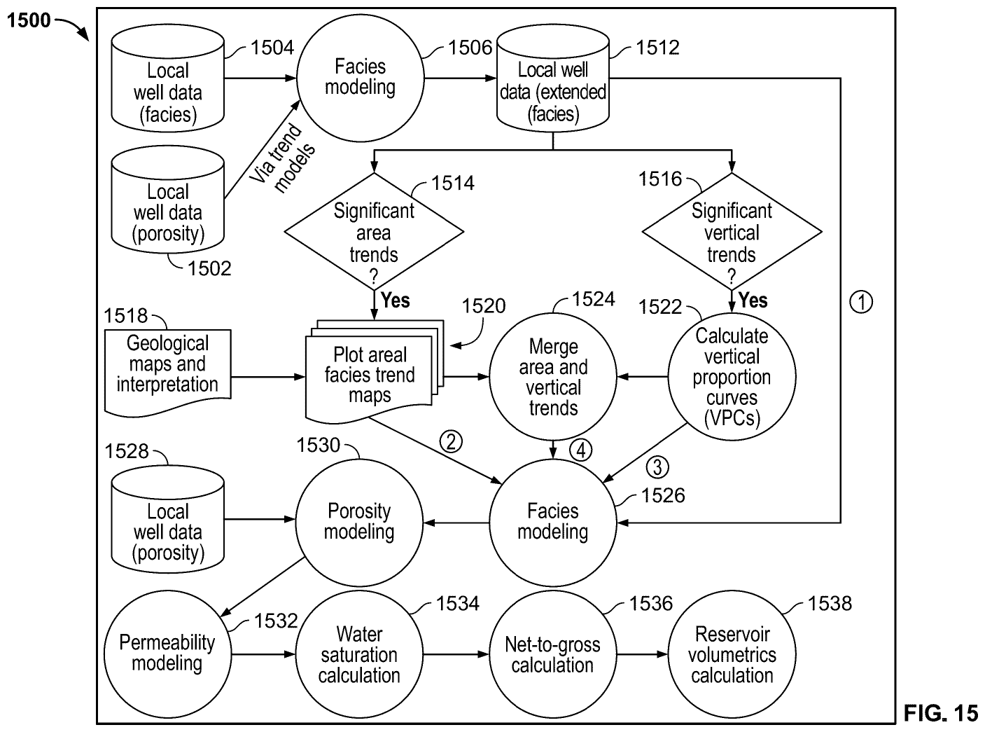

FIG. 15 illustrates a flow diagram 1500 for porosity-assistant facies modeling and reservoir properties modeling. A summary of the porosity-assisted facies and reservoir properties modeling process 1500 is now described. The difference is that porosity is used to assist facies modeling via facies probability trend models. The workflow of extracted facies probability information is illustrated in FIG. 3 as process 300. The process 1500 combines process 300 with process 100.

For process 1500, the data processing system is configured to retrieve data from well logs of the reservoir. As previously described, the well logs include wireline data representing one or more features of the subsurface. The well logs include porosity data 1502 that is measured directly from the subsurface using sensors within the wells. The well logs also include facies data 1504 which is calculated from one or more other measurements of the well log data as previously described. In some implementations, the facies data are determined based on coring the drilled well.

The data processing system is configured to calculate and combine facies proportions for wells with facies and porosity inputs. Specifically, the process 1500 includes determining, by the data processing system at step 1506, facies proportions per-well that are facies-based. The data processing system determines the facies proportions based on the facies 1504.

The process 1500 includes determining, by the data processing system at step 1506, facies probability functions, as previously described. The data processing system generates the facies probability functions at step 1506 using both the facies data 1504 and the porosity data 1502. The data processing system uses the generated faces probability functions to determine facies proportions per-well that are based on porosity. The data processing system, in process 1500, is configured to merge and porosity-based facies proportions that were previously generated, as described in relation to FIG. 3.

The reservoir properties modeling process 1500 of FIG. 15 includes, at step 1512, obtaining well log data from wells in the subsurface of the reservoir being modeled. Specifically, facies data are retrieved from a local well database. the facies data our data that are included in well logs that represent the different types of facies detected at each of the well locations represented by the well logs. For example, the local well data can include wireline data obtained from one or more wells in the reservoir. Generally, the facies at each of the one or more wells are determined based on an initial facies modeling workflow. For example, each of the data represented in the wireline log can be characterized to represent one or more different facies. For example, when one or more different types of data in the well logs are within predefined ranges, those data together can be determined to correspond to a particular facies (e.g., using neural networks), as subsequently described.

Generally, the process 1500 includes facies modeling, followed by porosity modeling by facies, permeability modeling co-simulated by porosity, water saturation calculation, net-to-gross calculation, and reservoir volumetric calculation, As subsequently described. With this process 1500, The data processing system models all reservoir properties (e.g., sequentially). Specifically, in this initial process 1500, the data processing system incorporates porosity data into the model after the facies model is ready. Depending on the availability of the areal and vertical trends, there are four choices of facies modeling workflows.

The facies modeling of process 1500 is now described in detail. The data processing system executing the process 1500 is configured to determine, at step 104, whether there are significant areal trends represented in the log data of the one or more wells. An areal trend refers to a trend, in values of one or more data types of the wireline data logs, that exists over an area of the subsurface. The data processing system executing process 1500 is also configured to determine, at step 1516, whether there are significant vertical trends in the data of the well logs. a vertical trend refers to a trend, in values of the one or more data types of the wireline data logs, that exists over a vertical region of the subsurface. Depending on the availability of the areal and vertical trends, there are four options of facies modeling.

In process 1500, the data processing system is configured to perform facies modeling in situations in which there are no significant aerial trends or significant vertical trends, as now described. In FIG. 15, this is shown as option 1. In this example, the data processing system is configured to generate the facies model, at step 1526, with well data input only. The facies percentages derived from wells, and the variograms derived from facies data are used as the main inputs, so the facies model is data-driven. In this example, a geomodeler and a geologist generally verify variogram orientation and ranges of the facies model and perform a quality control check for the resulting facies model. The validation ensures that simulated facies model follows the geological conceptual model and knowledge, because the data processing system uses the resulting facies models to constrain the succeeding porosity model.

In process 1500, the data processing system is configured to perform facies modeling in situations in which there are aerial trends but not significant vertical trends, as now described. In FIG. 15, this is shown as option 2. If there are significant areal trends, the data processing system plots, at step 1520, the facies areal trend maps and uses them as input for facies modeling add step 1526. Well data are preferentially drilled and typically cannot cover the whole area of interest (AOI). Geological knowledge, the conceptual facies model, and geological maps are received, at step 1528, and used as input data to predict or establish the trend maps, ensuring that those maps make geological sense. For a geostatistical simulation, commonly probability maps are integrated only, so the facies trend maps are typically facies probability maps, instead of facies thickness maps.

In process 1500, the data processing system is configured to perform facies modeling in situations in which there are no aerial trends but there are significant vertical trends, as now described. In FIG. 15, this is shown as option 3. If there are significant vertical trends, the data processing system generates, at step 1522, vertical proportion curves (VPCs) and uses these as input for facies modeling at step 1526. When a sequence-stratigraphic framework is applied for geological grid building, vertical trends are usually clear because of how the sequences are defined. The VPCs are usually data-driven by well log data and calculated on a layer-by-layer basis. The generated VPCs may be modified if the well data are either not enough or too sparse to capture the trend of vertical variations.

In process 1500, the data processing system is configured to perform facies modeling in situations in which there are both aerial trends and vertical trends, as now described. In FIG. 15, this is shown as option 4. If both lateral and vertical trends exist, the data processing system merges the lateral and vertical trends as a consistent three-dimensional trend model. The data processing system merges the plotted aerial facies trend maps and calculated VPC's into a consistent 3D trend model. The data processing system uses the combined trend model for facies modeling at step 1526.

Once the facies are modeled at step 1526, the data processing system proceeds to model the porosity of the reservoir. The data processing system receives, at step 1528, porosity data from the well log data. In process 1500, the data processing system is configured to perform, at step 1532, permeability modeling of the reservoir. in process 100, the data processing system is configured to perform, at step 1534, water saturation calculations. The data processing system can then perform, at step 1536, a net to gross calculation, and reservoir volumetrics calculations at step 1538. Steps 1532, 1534, 1536, and 1538 of process 1500 are used to predict where in the reservoir hydrocarbons may be present. These models are used to guide drilling operations in the reservoir or other hydrocarbon extraction operations in the reservoir.

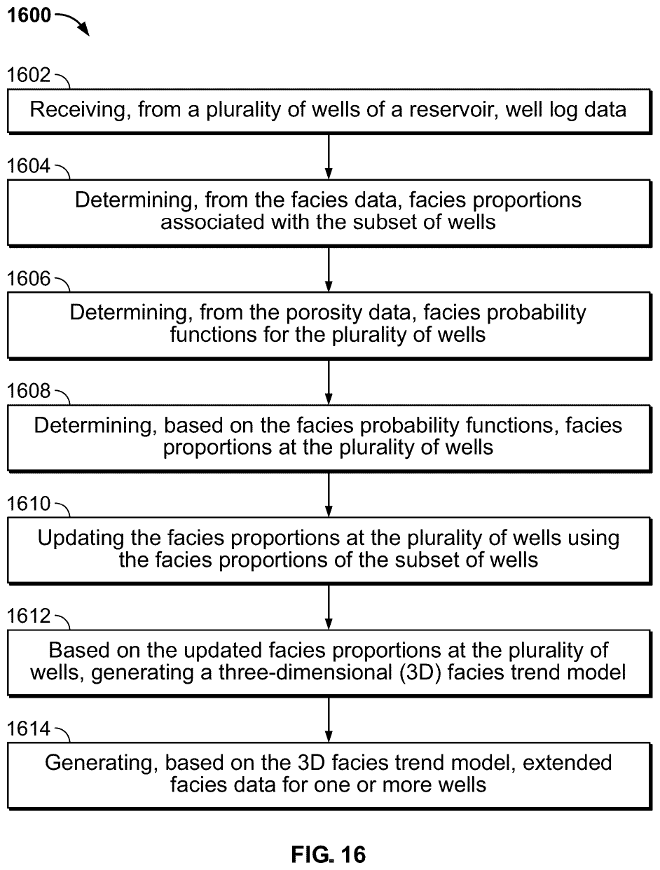

FIG. 16 illustrates a flow diagram for a process 1600 for porosity-assisted facies modeling. The process 1600 for extracting hydrocarbons from a subsurface region includes receiving (1602), from a plurality of wells of a reservoir, well log data measured by sensors in each of the wells of the plurality of wells, the well log data representing porosity measurements of the subsurface region at each of the wells of the plurality, wherein at least a subset of the wells are associated with facies data representing facies at the subset of the wells. The process 1600 includes determining (1604), from the facies data, facies proportions associated with the subset of wells. The process 1600 includes determining (1606), from the porosity data, facies probability functions for the plurality of wells. The process 1600 includes determining (1608), based on the facies probability functions, facies proportions at the plurality of wells. The process 1600 includes updating (1610) the facies proportions at the plurality of wells using the facies proportions of the subset of wells. The process 1600 includes, based on the updated facies proportions at the plurality of wells, generating (1612) a three-dimensional (3D) facies trend model for the subsurface region at each of the wells of the plurality. The process 1600 includes generating (1614), based on the 3D facies trend model, extended facies data for one or more wells of the plurality of wells that are not in the subset of wells that are associated with facies data.

In some implementations the process 1600 includes determining, based on the extended facies data, reservoir volumetrics data for the subsurface region. In some implementations the process 1600 includes determining, based on the reservoir volumetrics data, a location in the subsurface region that includes hydrocarbon deposits.

In some implementations the process 1600 includes drilling, at the location in the subsurface region, a well.

In some implementations the process 1600 includes receiving geological maps data, generating an areal trend map, and generating, based on the areal trend map, the 3D facies trend model.

In some implementations the process 1600 includes detecting, in the facies data of the well log data, vertical trends in facies in the subsurface region. In some implementations the process 1600 includes generating vertical proportion curves from the vertical trends in the facies data. In some implementations the process 1600 includes generating, based on the vertical proportion curves, the 3D facies trend model.

In some implementations, the extended facies data represent facies that are present at each of the plurality of wells. In some implementations, the subset of wells include cored wells from which facies data are directly measured.

FIG. 17 is a block diagram of an example computing system 1700 used to provide computational functionalities associated with described algorithms, methods, functions, processes, flows, and procedures described in the present disclosure, according to some implementations of the present disclosure. The illustrated computer 1702 is intended to encompass any computing device such as a server, a desktop computer, a laptop/notebook computer, a wireless data port, a smart phone, a personal data assistant (PDA), a tablet computing device, or one or more processors within these devices, including physical instances, virtual instances, or both. The computer 1702 can include input devices such as keypads, keyboards, and touch screens that can accept user information. Also, the computer 1702 can include output devices that can convey information associated with the operation of the computer 1702. The information can include digital data, visual data, audio information, or a combination of information. The information can be presented in a graphical user interface (UI) (or GUI).

The computer 1702 can serve in a role as a client, a network component, a server, a database, a persistency, or components of a computer system for performing the subject matter described in the present disclosure. The illustrated computer 1702 is communicably coupled with a network 1724. In some implementations, one or more components of the computer 1702 can be configured to operate within different environments, including cloud-computing-based environments, local environments, global environments, and combinations of environments.

At a high level, the computer 1702 is an electronic computing device operable to receive, transmit, process, store, and manage data and information associated with the described subject matter. According to some implementations, the computer 1702 can also include, or be communicably coupled with, an application server, an email server, a web server, a caching server, a streaming data server, or a combination of servers.

The computer 1702 can receive requests over network 1724 from a client application (for example, executing on another computer 1702). The computer 1702 can respond to the received requests by processing the received requests using software applications. Requests can also be sent to the computer 1702 from internal users (for example, from a command console), external (or third) parties, automated applications, entities, individuals, systems, and computers.

Each of the components of the computer 1702 can communicate using a system bus 1704. In some implementations, any or all the components of the computer 1702, including hardware or software components, can interface with each other or the interface 1706 (or a combination of both), over the system bus 1704. Interfaces can use an application programming interface (API) 1714, a service layer 1716, or a combination of the API 1714 and service layer 1716. The API 1714 can include specifications for routines, data structures, and object classes. The API 1714 can be either computer-language independent or dependent. The API 1714 can refer to a complete interface, a single function, or a set of APIs.

The service layer 1716 can provide software services to the computer 1702 and other components (whether illustrated or not) that are communicably coupled to the computer 1702. The functionality of the computer 1702 can be accessible for all service consumers using this service layer. Software services, such as those provided by the service layer 1716, can provide reusable, defined functionalities through a defined interface. For example, the interface can be software written in JAVA, C++, or a language providing data in extensible markup language (XML) format. While illustrated as an integrated component of the computer 1702, in alternative implementations, the API 1714 or the service layer 1716 can be stand-alone components in relation to other components of the computer 1702 and other components communicably coupled to the computer 1702. Moreover, any or all parts of the API 1714 or the service layer 1716 can be implemented as child or sub-modules of another software module, enterprise application, or hardware module without departing from the scope of the present disclosure.

The computer 1702 includes an interface 1706. Although illustrated as a single interface 1706 in FIG. 17, two or more interfaces 1706 can be used according to needs, desires, or particular implementations of the computer 1702 and the described functionality. The interface 1706 can be used by the computer 1702 for communicating with other systems that are connected to the network 1724 (whether illustrated or not) in a distributed environment. Generally, the interface 1706 can include, or be implemented using, logic encoded in software or hardware (or a combination of software and hardware) operable to communicate with the network 1724. More specifically, the interface 1706 can include software supporting one or more communication protocols associated with communications. As such, the network 1724 or the hardware of the interface can be operable to communicate physical signals within and outside of the illustrated computer 1702.

The computer 1702 includes a processor 1708. Although illustrated as a single processor 1708 in FIG. 17, two or more processors 1708 can be used according to particular implementations of the computer 1702 and the described functionality. Generally, the processor 1708 can execute instructions and can manipulate data to perform the operations of the computer 1702, including operations using algorithms, methods, functions, processes, flows, and procedures as described in the present disclosure.

The computer 1702 also includes a database 1720 that can hold data (for example, seismic data 1722) for the computer 1702 and other components connected to the network 1724 (whether illustrated or not). For example, database 1720 can be an in-memory, conventional, or a database storing data consistent with the present disclosure. In some implementations, database 1720 can be a combination of two or more different database types (for example, hybrid in-memory and conventional databases) according to particular implementations of the computer 1702 and the described functionality. Although illustrated as a single database 1720 in FIG. 17, two or more databases (of the same, different, or combination of types) can be used according to particular implementations of the computer 1702 and the described functionality. While database 1720 is illustrated as an internal component of the computer 1702, in alternative implementations, database 1720 can be external to the computer 1702.

The computer 1702 also includes a memory 1710 that can hold data for the computer 1702 or a combination of components connected to the network 1724 (whether illustrated or not). Memory 1710 can store any data consistent with the present disclosure. In some implementations, memory 1710 can be a combination of two or more different types of memory (for example, a combination of semiconductor and magnetic storage) according to implementations of the computer 1702 and the described functionality. Although illustrated as a single memory 1710 in FIG. 17, two or more memories 1710 (of the same, different, or combination of types) can be used according to implementations of the computer 1702 and the described functionality. While memory 1710 is illustrated as an internal component of the computer 1702, in alternative implementations, memory 1710 can be external to the computer 1702.

The application 1712 can be an algorithmic software engine providing functionality according to implementations of the computer 1702 and the described functionality. For example, application 1712 can serve as one or more components, modules, or applications. Further, although illustrated as a single application 1712, the application 1712 can be implemented as multiple applications 1712 on the computer 1702. In addition, although illustrated as internal to the computer 1702, in alternative implementations, the application 1712 can be external to the computer 1702.

The computer 1702 can also include a power supply 1718. The power supply 1718 can include a rechargeable or non-rechargeable battery that can be configured to be either user-or non-user-replaceable. In some implementations, the power supply 1718 can include power-conversion and management circuits, including recharging, standby, and power management functionalities. In some implementations, the power-supply 1718 can include a power plug to allow the computer 1702 to be plugged into a wall socket or a power source to, for example, power the computer 1702 or recharge a rechargeable battery.

There can be any number of computers 1702 associated with, or external to, a computer system containing computer 1702, with each computer 1702 communicating over network 1724. Further, the terms “client,” “user,” and other appropriate terminology can be used interchangeably, as appropriate, without departing from the scope of the present disclosure. Moreover, the present disclosure contemplates that many users can use one computer 1702 and one user can use multiple computers 1702.

Implementations of the subject matter and the functional operations described in this specification can be implemented in digital electronic circuitry, in tangibly embodied computer software or firmware, in computer hardware, including the structures disclosed in this specification and their structural equivalents, or in combinations of one or more of them. Software implementations of the described subject matter can be implemented as one or more computer programs. Each computer program can include one or more modules of computer program instructions encoded on a tangible, non-transitory, computer-readable computer-storage medium for execution by, or to control the operation of, data processing apparatus. Alternatively, or additionally, the program instructions can be encoded in/on an artificially generated propagated signal. The example, the signal can be a machine-generated electrical, optical, or electromagnetic signal that is generated to encode information for transmission to suitable receiver apparatus for execution by a data processing apparatus. The computer-storage medium can be a machine-readable storage device, a machine-readable storage substrate, a random or serial access memory device, or a combination of computer-storage mediums.

Computer readable media (transitory or non-transitory, as appropriate) suitable for storing computer program instructions and data can include all forms of permanent/non-permanent and volatile/non-volatile memory, media, and memory devices. Computer readable media can include, for example, semiconductor memory devices such as random-access memory (RAM), read only memory (ROM), phase change memory (PRAM), static random-access memory (SRAM), dynamic random-access memory (DRAM), erasable programmable read-only memory (EPROM), electrically erasable programmable read-only memory (EEPROM), and flash memory devices. Computer readable media can also include, for example, magnetic devices such as tape, cartridges, cassettes, and internal/removable disks. Computer readable media can also include magneto optical disks and optical memory devices and technologies including, for example, digital video disc (DVD), CD ROM, DVD+/-R, DVD-RAM, DVD-ROM, HD-DVD, and BLURAY. The memory can store various objects or data, including caches, classes, frameworks, applications, modules, backup data, jobs, web pages, web page templates, data structures, database tables, repositories, and dynamic information. Types of objects and data stored in memory can include parameters, variables, algorithms, instructions, rules, constraints, and references. Additionally, the memory can include logs, policies, security or access data, and reporting files. The processor and the memory can be supplemented by, or incorporated in, special purpose logic circuitry.

Any claimed implementation is applicable to at least a computer-implemented method; a non-transitory, computer-readable medium storing computer-readable instructions to perform the computer-implemented method; and a computer system comprising a computer memory interoperable coupled with a hardware processor configured to perform the computer-implemented method or the instructions stored on the non-transitory, computer-readable medium.

While this specification contains many specific implementation details, these should not be construed as limitations on the scope of what may be claimed, but rather as descriptions of features that may be specific to implementations. Certain features that are described in this specification in the context of separate implementations can also be implemented, in combination, in a single implementation. Conversely, various features that are described in the context of a single implementation can also be implemented in multiple implementations, separately, or in any suitable sub-combination. Moreover, although previously described features may be described as acting in certain combinations and even initially claimed as such, one or more features from a claimed combination can, in some cases, be excised from the combination, and the claimed combination may be directed to a sub-combination or variation of a sub-combination.

What is claimed is:

1. A method for porosity-assisted facies modeling for extracting hydrocarbons from a subsurface region, the method comprising:
receiving, from a plurality of wells of a reservoir, well log data measured by sensors in each of the wells of the plurality of wells, the well log data representing porosity measurements of the subsurface region at each of the wells of the plurality, wherein at least a subset of the wells are associated with facies data representing facies at the subset of the wells;
determining, from the facies data, facies proportions associated with the subset of wells;
determining, from the porosity data, facies probability functions for the plurality of wells;
determining, based on the facies probability functions, facies proportions at the plurality of wells;
updating the facies proportions at the plurality of wells using the facies proportions of the subset of wells;
based on the updated facies proportions at the plurality of wells, generating a three-dimensional (3D) facies trend model for the subsurface region at each of the wells of the plurality; and
generating, based on the 3D facies trend model, extended facies data for one or more wells of the plurality of wells that are not in the subset of wells that are associated with facies data.

2. The method of claim 1, further comprising:
determining, based on the extended facies data, reservoir volumetrics data for the subsurface region; and
determining, based on the reservoir volumetrics data, a location in the subsurface region that includes hydrocarbon deposits.

3. The method of claim 2, further comprising:
drilling, at the location in the subsurface region, a well.

4. The method of claim 1, further comprising:
receiving geological maps data;
generating an areal trend map; and
generating, based on the areal trend map, the 3D facies trend model.

5. The method of claim 1, further comprising:
detecting, in the facies data of the well log data, vertical trends in facies in the subsurface region;
generating vertical proportion curves from the vertical trends in the facies data; and
generating, based on the vertical proportion curves, the 3D facies trend model.

6. The method of claim 1, wherein the extended facies data represent facies that are present at each of the plurality of wells.

7. The method of claim 1, wherein the subset of wells include cored wells from which facies data are directly measured.

8. A system for extracting hydrocarbons from a subsurface region, the system comprising:
at least one processor; and
a memory storing instructions that, when executed by the at least one processor, cause the at least one processor to perform operations comprising:
receiving, from sensors in each of a plurality of wells of a reservoir, well log data measured by sensors in each of the wells of the plurality of wells, the well log data representing porosity measurements of the subsurface region at each of the wells of the plurality, wherein at least a subset of the wells are associated with facies data representing facies at the subset of the wells;
determining, from the facies data, facies proportions associated with the subset of wells;
determining, from the porosity data, facies probability functions for the plurality of wells;
determining, based on the facies probability functions, facies proportions at the plurality of wells;
updating the facies proportions at the plurality of wells using the facies proportions of the subset of wells;
based on the updated facies proportions at the plurality of wells, generating a three-dimensional (3D) facies trend model for the subsurface region at each of the wells of the plurality; and
generating, based on the 3D facies trend model, extended facies data for one or more wells of the plurality of wells that are not in the subset of wells that are associated with facies data.

9. The system of claim 8, the operations further comprising:
determining, based on the extended facies data, reservoir volumetrics data for the subsurface region; and
determining, based on the reservoir volumetrics data, a location in the subsurface region that includes hydrocarbon deposits.

10. The system of claim 9, further comprising a drill, wherein the operations further comprise:
drilling, at the location in the subsurface region, a well using the drill.

11. The system of claim 8, the operations further comprising:
receiving geological maps data;
generating an areal trend map; and
generating, based on the areal trend map, the 3D facies trend model.

12. The system of claim 8, the operations further comprising:
detecting, in the facies data of the well log data, vertical trends in facies in the subsurface region;
generating vertical proportion curves from the vertical trends in the facies data; and
generating, based on the vertical proportion curves, the 3D facies trend model.

13. The system of claim 8, wherein the extended facies data represent facies that are present at each of the plurality of wells.

14. The system of claim 8, wherein the subset of wells include cored wells from which facies data are directly measured.

15. One or more non-transitory computer-readable media storing instructions to cause at least one processor to perform operations comprising:
receiving, from sensors in each of a plurality of wells of a reservoir, well log data measured by sensors in each of the wells of the plurality of wells, the well log data representing porosity measurements of a subsurface region at each of the wells of the plurality, wherein at least a subset of the wells are associated with facies data representing facies at the subset of the wells;
determining, from the facies data, facies proportions associated with the subset of wells;
determining, from the porosity data, facies probability functions for the plurality of wells;
determining, based on the facies probability functions, facies proportions at the plurality of wells;
updating the facies proportions at the plurality of wells using the facies proportions of the subset of wells;
based on the updated facies proportions at the plurality of wells, generating a three-dimensional (3D) facies trend model for the subsurface region at each of the wells of the plurality; and
generating, based on the 3D facies trend model, extended facies data for one or more wells of the plurality of wells that are not in the subset of wells that are associated with facies data.

16. The one or more non-transitory computer-readable media of claim 15, the operations further comprising:
determining, based on the extended facies data, reservoir volumetrics data for the subsurface region; and
determining, based on the reservoir volumetrics data, a location in the subsurface region that includes hydrocarbon deposits.

17. The one or more non-transitory computer-readable media of claim 16, the operations further comprising:
generating a control signal based on the determined location in the subsurface region; and
region based on the control signal, controlling drilling of a well at the location in a subsurface.

18. The one or more non-transitory computer-readable media of claim 15, the operations further comprising:
receiving geological maps data;
generating an areal trend map; and
generating, based on the areal trend map, the 3D facies trend model.

19. The one or more non-transitory computer-readable media of claim 15, the operations further comprising:
detecting, in the facies data of the well log data, vertical trends in facies in the subsurface region;
generating vertical proportion curves from the vertical trends in the facies data; and
generating, based on the vertical proportion curves, the 3D facies trend model.

20. The one or more non-transitory computer-readable media of claim 15, wherein the extended facies data represent facies that are present at each of the plurality of wells.
